(19) United States
(12) Patent Application Publication
(10) Pub. No.: US 2024/0387582 A1
(43) Pub. Date: Nov. 21, 2024

(54) ULTRA-WIDE FIELD-OF-VIEW PINHOLE COMPOUND EYE USING HEMISPHERICAL NANOWIRE ARRAY FOR ROBOTIC VISION

(71) Applicant: The Hong Kong University of Science and Technology, Hong Kong (CN)

(72) Inventors: Zhiyong FAN, Hong Kong (CN); Yu ZHOU, Hong Kong (CN)

(21) Appl. No.: 18/647,909

(22) Filed: Apr. 26, 2024

Related U.S. Application Data
(60) Provisional application No. 63/502,922, filed on May 18, 2023.

(51) Int. Cl. H01L 27/146; B33Y 80/00; G02B 5/20; H01L 31/0352; H01L 31/18

(52) U.S. Cl. CPC H01L 27/14625; G02B 5/201; H01L 27/14607; H01L 27/14683; H01L 31/0352; H01L 31/1884; B33Y 80/00

(57) ABSTRACT

A pinhole compound eye (PHCE) system includes: a pinhole array comprising a plurality of pinholes, wherein the pinhole array is configured to receive light from varying incident angles; and a detector array comprising a plurality of nanowires, wherein the detector array is positioned at a concave surface of the pinhole array and is configured to detect light passing through the pinhole array.

### CROSS-REFERENCE TO RELATED APPLICATIONS

This application claims the benefit of U.S. Provisional Application No. 63/502,922 titled “ULTRA-WIDE FIELD-OF-VIEW PINHOLE COMPOUND EYE USING HEMISPHERICAL NANOWIRE ARRAY FOR ROBOTIC VISION,” filed May 18, 2023, the entire content of which is incorporated herein by reference.

### FIELD

This disclosure relates generally to vision technology and, more specifically, to lens-free artificial compound eye systems.

### BACKGROUND

Diverse biological vision systems exist in nature. Natural compound eyes (CEs) with extraordinary visual capabilities, such as wide field-of-view (FoV) and fast motion tracking, offer tremendous attraction for practical applications especially for robotic systems. Inspired by this, a plethora of artificial CEs have been widely explored, which are mostly fabricated by transferring microlens array (MLA) on curved substrates and further integrated with commercial planar image sensors. In this case, the imaging ability of CEs is highly limited by the tricky transfer process in which uniformity is difficult to control. And it inevitably causes the mismatch between three-dimensional (3D) optical structures with underlying planar commercial imagers.

To ameliorate the problem, two promising strategies are explored based on advanced micro-nano fabrication and soft electronics. In one approach, optical structures with MLA are shaped precisely on curved surfaces through photopolymerization, laser writing, laser-assisted etching, microfluid-assisted moulding, or 3D printing. The optical structures are further assembled on planar imagers with the aid of complex waveguide units and costly lens systems. In another approach, deformable electronics enable the whole compound systems to transform into curvy shapes via elastomeric transfer, origami, or kirigami. This partly solves the mismatch issue, but still poses the challenges of deformation stability, limited number of pixels, and large unused space between imaging pixels for stress release. For instance, direct deformation to hemispherical configuration generates large residual stress, regarded as a risk of mechanical instability for a working CE. Limited by the abovementioned bottlenecks, there are very few reports on the function demonstration of compact CE systems integrated autonomous platforms such as robots or drones.

### SUMMARY

A first aspect of the present disclosure provides a pinhole compound eye (PHCE) system, the system comprising: a pinhole array comprising a plurality of pinholes, wherein the pinhole array is configured to receive light from varying incident angles; and a detector array comprising a plurality of nanowires, wherein the detector array is positioned at a concave surface of the pinhole array and is configured to detect light passing through the pinhole array.

According to an implementation of the first aspect, the pinhole array is confined within a honeycombed hemispherical structure.

According to an implementation of the first aspect, the honeycombed hemispherical structure with the pinhole array is 3D-printed.

According to an implementation of the first aspect, the plurality of nanowires are inside a plurality of pores within a hemispherical membrane template.

According to an implementation of the first aspect, the hemispherical membrane template is a hemispherical porous alumina membrane (PAM), and each pore of the plurality of pores corresponds to a subset of nanowires of the plurality of nanowires.

According to an implementation of the first aspect, each nanowire of the plurality of nanowires comprises a perovskite nanowire section and a residual nanowire section.

According to an implementation of the first aspect, the perovskite nanowire sections are positioned proximate to the pinhole array, and the residual nanowire sections are connected to a control circuit.

According to an implementation of the first aspect, each nanowire of the plurality of nanowires is aligned with a corresponding pinhole of the plurality of pinholes, and each pinhole is associated with a pixel of the detector array.

According to an implementation of the first aspect, the detector array comprises a plurality of pixels corresponding to the plurality of pinholes in the pinhole array, the plurality of pixels are connected to a control circuit through a plurality of contacts, and each pixel of the plurality of pixels corresponds to a contact of the plurality of contacts.

According to an implementation of the first aspect, each nanowire is arranged to receive light from the corresponding pinhole and one or more adjacent pinholes of the plurality of pinholes.

According to an implementation of the first aspect, the system further comprises a control circuit connected to the detector array and configured to obtain detection results from the detector array, wherein the control circuit comprises a readout circuit configured to read values from the plurality of nanowires in the detector array based on the light detected by the plurality of nanowires.

According to an implementation of the first aspect, the system further comprises: a second pinhole array comprising a plurality of pinholes distributed, wherein the second pinhole array is configured to receive light from varying incident angles; a second detector array comprising a plurality of nanowires, wherein the second detector array positioned at a concave surface of the second pinhole array and configured to detect light passing through the second pinhole array; and a frame, wherein the first pinhole array with the corresponding first detector array and the second pinhole array with the corresponding second detector array are mounted on the frame.

According to an implementation of the first aspect, the first pinhole array with the corresponding first detector array corresponds to a first field of view, the second pinhole array with the corresponding second detector array corresponds to a second field of view, and the first field of view and the second field of view have an overlapping region.

A second aspect of the present disclosure provides a method for fabricating a pinhole compound eye (PHCE) system, the method comprising: fabricating a hemispherical structure comprising a pinhole array with a plurality of pinholes distributed along a surface of the hemispherical structure; fabricating a hemispherical membrane template comprising a plurality of pores distributed along a surface of the hemispherical membrane template; growing nanowires inside the plurality of pores of the hemispherical membrane template to form a nanowire array; assembling the hemispherical structure and the hemispherical membrane template by aligning the pinhole array with the nanowire array; and fabricating a plurality of contacts coupled to the nanowire array in the hemispherical membrane template.

According to an implementation of the second aspect, the hemispherical structure is a honeycombed hemispherical structure, and the hemispherical structure with the pinhole array is 3D-printed.

According to an implementation of the second aspect, growing the nanowires inside the plurality of pores of the hemispherical membrane template to form the nanowire array comprises: growing residual nanowires inside the plurality of pores of the hemispherical membrane template; and growing perovskite nanowires onto the residual nanowires inside the plurality of pores of the hemispherical membrane template.

According to an implementation of the second aspect, the method further comprises fabricating a common electrode layer onto the perovskite nanowires within the hemispherical membrane template, wherein the plurality of contacts are coupled to the residual nanowires within the hemispherical membrane template.

According to an implementation of the second aspect, the common electrode layer comprises Indium Tin Oxide (ITO), and the plurality of contacts are made of Indium.

A third aspect of the present disclosure provides a method for detecting an object, the method comprising: receiving light via a pinhole array (PHA) of a pinhole compound eye (PHCE) system, wherein respective pinholes of the pinhole array receive light corresponding to varying incident angles; detecting, through a nanowire array of the PHCE system, a light intensity distribution across a plurality of pixels associated with the PHA; and constructing an image frame based on the detected light intensity distribution across the plurality of pixels.

According to an implementation of the third aspect, one or more nanowires of the nanowire array is aligned with a corresponding pinhole of the PHA, and wherein each pinhole of the PHA is associated with one or more pixels of the plurality of pixels.

### BRIEF DESCRIPTION OF THE DRAWINGS

FIG. 1A is a block diagram of an exemplary vision system, in accordance with one or more exemplary embodiments of the present disclosure.

FIG. 1B is a block diagram of an exemplary pinhole compound eye (PHCE) system, in accordance with one or more exemplary embodiments of the present disclosure.

FIG. 1C is a block diagram of an exemplary computing system, in accordance with one or more exemplary embodiments of the present disclosure.

FIG. 1D is a block diagram of an exemplary user interface (UI), in accordance with one or more exemplary embodiments of the present disclosure.

FIG. 2A illustrates an exemplary PHCE device, in accordance with one or more exemplary embodiments of the present disclosure, in accordance with one or more exemplary embodiments of the present disclosure.

FIG. 2B is an exploded view of the exemplary PHCE device of FIG. 2A, in accordance with one or more exemplary embodiments of the present disclosure.

FIG. 2C provides a magnified cross-section view of a boxed section depicted in FIG. 2A, in accordance with one or more exemplary embodiments of the present disclosure.

FIG. 2D is a side-view image of a PHCE system mounted on printed circuit boards, in accordance with one or more exemplary embodiments of the present disclosure.

FIG. 3 is a scanning-electron microscope (SEM) image of a hemispherical porous alumina membrane (PAM) with nanowires grown inside, in accordance with one or more exemplary embodiments of the present disclosure.

FIG. 4 is a process flow for fabricating a nanowire (NW) array detector, in accordance with one or more exemplary embodiments of the present disclosure.

FIGS. 5A-F are characteristics of various perovskite materials.

FIG. 6 is an exemplary layout of the pinholes in a pinhole array (PHA), in accordance with one or more exemplary embodiments of the present disclosure.

FIGS. 7A and 7B are characteristics of the PHA, in accordance with one or more exemplary embodiments of the present disclosure.

FIG. 8A illustrates an exemplary measurement setup for a monocular vision system, in accordance with one or more exemplary embodiments of the present disclosure.

FIG. 8B is an exemplary visualization of the measurement result for field of view, in accordance with one or more exemplary embodiments of the present disclosure.

FIGS. 8C and 8D are visualizations of exemplary patterns captured by the monocular vision system with the measurement setup as demonstrated in FIG. 8A.

FIG. 9A shows an exemplary binocular vision system, in accordance with one or more exemplary embodiments of the present disclosure.

FIG. 9B illustrates the working principle of a binocular vision system, in accordance with one or more exemplary embodiments of the present disclosure.

FIG. 9C shows calculated spatial positions and generated movement paths based on measurements taken by the binocular vision system.

FIG. 9D illustrates the working principle of on-drone motion tracking, in accordance with one or more exemplary embodiments of the present disclosure.

FIG. 10A is an image of a drone integrated with a PHCE system, in accordance with one or more exemplary embodiments of the present disclosure.

FIGS. 10B-10D compare digital images with the current maps captured at different moments by the drone with the PHCE system as shown in FIG. 10A.

FIG. 11A is an image of a PHCE system with an example control circuitry, in accordance with one or more exemplary embodiments of the present disclosure.

FIG. 11B is a block diagram illustrating various components in a control circuitry, in accordance with one or more exemplary embodiments of the present disclosure.

### DETAILED DESCRIPTION

Example embodiments of the present application provide a lens-free artificial compound eye (CE) vision system, comprising a pinhole array (PHA) optical component and an intrinsic convex hemispherical image sensor including a high-density perovskite nanowire array (PNA). The PHA is shaped in honeycombed anatomy, forming conformal contact with the underlying hemispherical imaging subsystem. Imager with PNA is further compositionally engineered to cover the visible and near-infrared spectral range with decent performance. The integrated pinhole compound eye (PHCE) system may acquire ultra-wide-angle panoramic images with a field-of-view (FoV) of 140°.

Furthermore, a binocular PHCE system is provided, which offers a widened FoV of 220° and enables stereopsis vision. The binocular PHCE system has successfully achieved target positioning in three-dimensional (3D) space. In an embodiment, a functional integration of the PHCE system on a flying drone has been demonstrated, enabling motion tracking of a quadruped robot on the ground. This unique air-ground collaborative robotic interaction demonstrates the potential of using the compound eye system of the present disclosure for the development of multi-robot collaboration and robot swarm technology in the future.

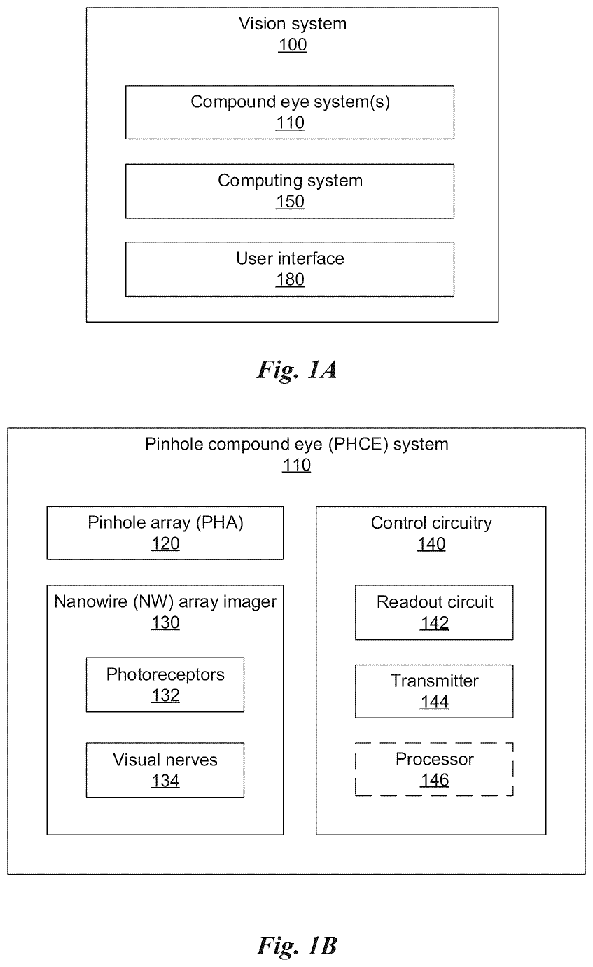

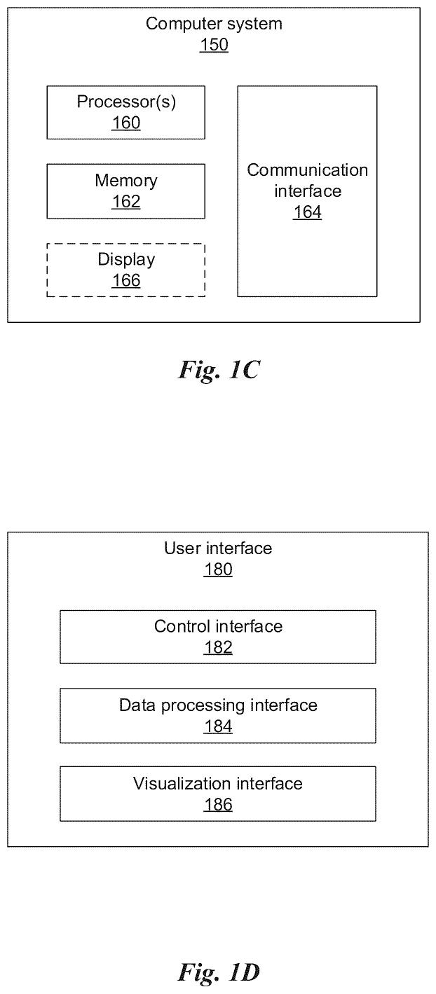

FIG. 1A is a block diagram of an exemplary vision system, in accordance with one or more exemplary embodiments of the present disclosure. As depicted in FIG. 1A, the vision system 100 includes various hardware and software components, such as one or more compound eye systems 110, a computing system 150, and a user interface (UI) 180. As further elaborated with reference to FIG. 1B, the compound eye system(s) 110 includes various optical and electrical components to detect vision information of a scene and transmit the acquired data. With reference to FIG. 1C, an example computing system 150 is described with further detail, which is configured to process the vision data (e.g., captured images) from the compound eye system(s) 110. The computing system 150 may employ various algorithms to facilitate suitable data processing. For example, the computing system may construct an image of the scene based on the vision information acquired within the field of view of the compound eye system(s) 110. In some examples, the constructed image may be a panoramic image. In further examples, the computing system 150 may detect motion/position of a target object based on the constructed images. This may enable the tracking of the target object in the scene. For example, the computing system 150 may generate one or more instructions to control the pose/position of the compound eye system(s) 110 (e.g., through a moving platform, such as a drone, a robotic arm, etc.) to follow the movement of the target object. An example UI 180 is described with reference to FIG. 1D, enabling interaction between a user and the vision system 100.

By way of example and not limitation, the vision system 100 and/or the computing system 150 may include or be embodied as a Personal Computer (“PC”), a laptop computer, a mobile device, a smartphone, a tablet computer, a virtual reality headset, a video player, a video camera, a vehicle, a virtual machine, a drone, a robot, a handheld communications device, a vehicle computer system, an embedded system controller, a workstation, an edge device, any combination of these delineated devices, or any other suitable device.

The vision system 100 may be operated in suitable network environments. Components of a network environment may communicate with each other via a network(s), which may be wired, wireless, or both. By way of example, the network may include one or more Wide Area Networks (“WANs”), one or more Local Area Networks (“LANs”), one or more public networks such as the Internet, and/or one or more private networks. Where the network includes a wireless telecommunications network, components such as a base station, a communications tower, access points, or other components may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices. In at least one embodiment, a network environment may include one or more cloud-based network environments, a distributed computing environment, a combination thereof, etc.

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). A cloud-based network environment may be private (e.g., limited to a single organization), may be public (e.g., available to many organizations), and/or a combination thereof (e.g., a hybrid cloud environment).

FIG. 1B is a block diagram of an exemplary pinhole compound eye (PHCE) system, in accordance with one or more exemplary embodiments of the present disclosure. The PHCE system of FIG. 1B is embodied as an exemplary compound eye system 110 as depicted in FIG. 1A. The PHCE system 110 includes various hardware and software components, such as optical and electrical components, as well as codes and instructions, to facilitate functions described in the present disclosure. As illustrated in FIG. 1B, the PHCE system 110 includes a pinhole array (PHA) 120, a nanowire (NW) array imager 130, and a control circuit 140, among other suitable components.

The PHA 120 includes a plurality of pinholes distributed along a curved surface. In an optical system, a pinhole is used to control the amount and direction of light entering the system. For example, a pinhole may act as a spatial filter, allowing only light rays that pass through the small aperture to continue on to an image plane or a sensing element of a detector. This helps to improve image sharpness, reduce aberrations, and control depth of field in the resulting images. That said, the PHA 120 is utilized to control the incident light entering the PHCE system 110. In some embodiments, the curved surface is a surface of a hemispherical structure. The incident light enters the PHCE system 110 from a convex surface, while the sensing elements (e.g., the nanowire (NW) array imager 130) receive light output from the concave surface of the hemispherical structure.

As will be further elaborated hereafter, the NW array imager 130 includes a plurality of perovskite nanowires, utilized to detect the optical signals passing through the PHA 120. The perovskite nanowires in the NW array imager 130 function as photoreceptors 132. The photoreceptors 132 are connected to a plurality of visual nerves 134. The perovskite nanowires 132 are made of suitable semiconductor material allowing light of a predefined ranged to be detected. For example, the bandgap of the perovskite nanowires may be customized by selecting different materials, doping conditions (e.g., dopant type or concentration), or other factors. This enables the control of the spectrum range detectable by the photoreceptors 132 of the NW array imager 130. When receiving the light within the detectable wavelength, the photoreceptors 132 convert the optical signal to an electrical signal (e.g., to electrical carriers, such as electrons and holes). The visual nerves 134, made of suitable metallic material, are connecting with metal wires, enabling the electrical signal generated by the corresponding photoreceptors 132 to be transmitted to the control circuitry 140.

In some embodiments, the plurality of nanowires of the NW array imager 130 are fabricated along a curved surface that conforms to the hemispherical structure corresponding to the PHA 120. The nanowires are aligned with the pinholes in the PHA 120, ensuring that the incident light passing through the PHA 120 is efficiently and effectively detected by the NW array imager 130. For example, each nanowire may be aligned with the center of a pinhole within the pinhole array. Alternatively, a subset of nanowires may be aligned with a pinhole within the pinhole array. In this configuration, the subset of nanowires may effectively detect the light passing through the respective pinhole, as well as potentially through one or more adjacent pinholes.

The control circuitry 140 includes various hardware and software components configured to obtain and/or process signals generated from the NW array imager 130 based on the light passing through the PHA 120. In this example, the control circuitry 140 includes a readout circuit 142, a transmitter 144, and a processor 146. The readout circuit 142 is connected to the NW array image 130 and configured to read out the signals generated by the plurality of nanowires in the NW array imager 130. For example, the incident light may induce carries (e.g., electrons/holes) in the plurality of nanowires, which may be read out by the readout circuit 142 in the form of current values. The transmitter 144 may include a suitable chip, electronic module, or semiconductor device, among other components, to enable data transmission from the PHCE system 110 to a computing system 150 in a suitable network environment. The processor 146 may execute instructions stored in a memory to facilitate controlling signal readout, data transmission, or other suitable operations (e.g., filtering, noise cancelling, etc.).

FIG. 1C is a block diagram of an exemplary computing system 150 configured to implement various functions, in accordance with one or more exemplary embodiments of the present disclosure. In some embodiments, the computing system 150 is integrated into a robotic system or an autonomous system (e.g., a drone or an autonomous vehicle) along with the vision system 100 (or the PHCE system 110). In these scenarios, the computing system 150 processes the data received from the vision system 100 (or the PHCE system 110) to generate instructions to control the robotic or autonomous system. For example, the computing system 150 may construct images based on the received data and perform positioning/tracking of a target object by controlling the movement of the robotic or autonomous system. For example, the computing system 150 may determine a subsequent movement for a robotic or autonomous system based on the detected motion of the target object according to the data from the vision system 100 or the PHCE system 110.

As shown in FIG. 1C, the computing system 150 may include one or more processors 160, a memory 162, a communication interface 164, and a display 166. The processor(s) 160 may be configured to perform the operations in accordance with the instructions stored in the memory 162. The processor(s) 160 may include any appropriate type of general-purpose or special-purpose microprocessor (e.g., a CPU or GPU, respectively), digital signal processor, microcontroller, or the like. The memory 162 may be configured to store computer-readable instructions that, when executed by the processor(s) 160, can cause the processor(s) 160 to perform various operations discussed herein. The memory 162 may be any non-transitory type of mass storage, such as volatile or non-volatile, magnetic, semiconductor-based, tape-based, optical, removable, non-removable, or other type of storage device or tangible computer-readable medium including, but not limited to, a read-only memory (“ROM”), a flash memory, a dynamic random-access memory (“RAM”), and/or a static RAM. Various processes/flowcharts described in terms of mathematics in the present disclosure may be realized in instructions stored in the memory 162, when executed by the processor(s) 160.

The communication interface 164 may be configured to communicate information between the computing system 150 and PHCE system 110 as depicted in FIGS. 1A-1C. In one example, the communication interface 164 may include an integrated services digital network (“ISDN”) card, a cable modem, a satellite modem, or a modem to provide a data communication connection. In another example, the communication interface 164 may include a local area network (“LAN”) card to provide a data communication connection to a compatible LAN. In a further example, the communication interface 164 may include a high-speed network adapter such as a fiber optic network adaptor, 10G Ethernet adaptor, or the like. Wireless links can also be implemented by the communication interface 164. In such an implementation, the communication interface 164 can send and receive electrical, electromagnetic or optical signals that carry digital data streams representing various types of information via a network. The network can typically include a cellular communication network, a Wireless Local Area Network (“WLAN”), a Wide Area Network (“WAN”), or the like.

The communication interface 164 may also include various I/O devices such as a keyboard, a mouse, a touchpad, a touch screen, a microphone, a camera, a biosensor, etc. A user may input data to the computing system 150 (e.g., a terminal device) through the communication interface 164.

The display 166 may be integrated as part of the computing system 150 or may be provided as a separate device communicatively coupled to the computing system 150. The display 166 may include a display device such as a liquid crystal display (“LCD”), a light emitting diode display (“LED”), a plasma display, or any other type of display, and provide a graphical user interface (“GUI”) presented on the display for user input and data depiction. In some embodiments, the display 166 may be integrated as part of the communication interface 164.

FIG. 1D is a block diagram of an exemplary user interface (UI) 180 configured to implement various functions, in accordance with one or more exemplary embodiments of the present disclosure. As shown in FIG. 1D, the UI 180 includes various functional modules, such as a control interface 182, a data processing interface 184, a visualization interface 186, among others.

The control interface 182 enables the user to configure various parameters to control the operation of the vision system 100 and/or a robotic system (or other types of systems) integrating the vision system 100. For example, the control interface 182 may allow the user to select from predefined configurations and/or input customized values, such as data acquisition periodicity, detection threshold, and other parameters.

The data processing interface 184 allows the user to implement various algorithms/techniques to process the data obtained by the control circuitry 140 of the PHCE system 110. For example, the user may choose from a selection of image processing algorithms to construct images and/or suppressing background noise based on the detected vision information.

The visualization interface 186 displays various visualizations based on the output from the control interface 182 and/or the data processing interface 184. In one example, the visualization interface 186 may display selected configurations from the control interface 182 and/or the data processing interface 184. In another example, the visualization interface 186 may display constructed image frames output from the data processing interface 184.

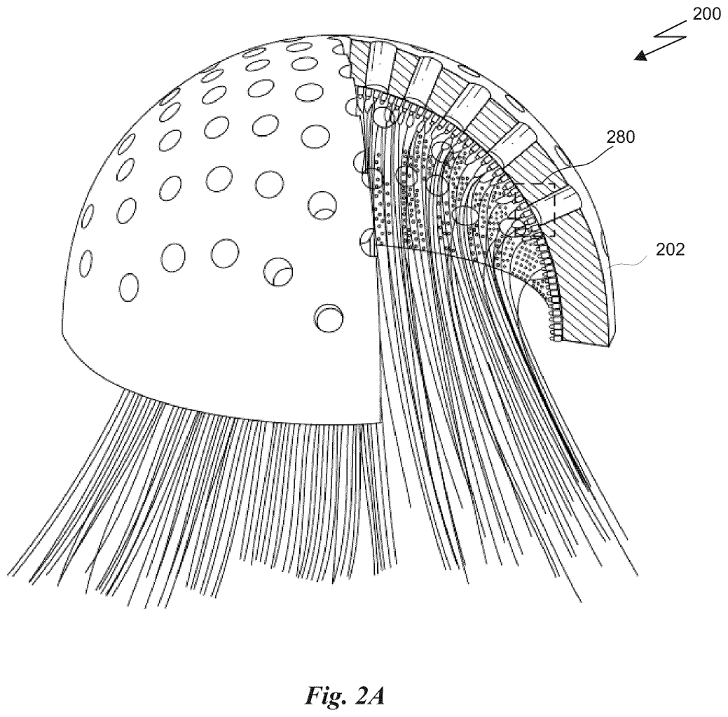

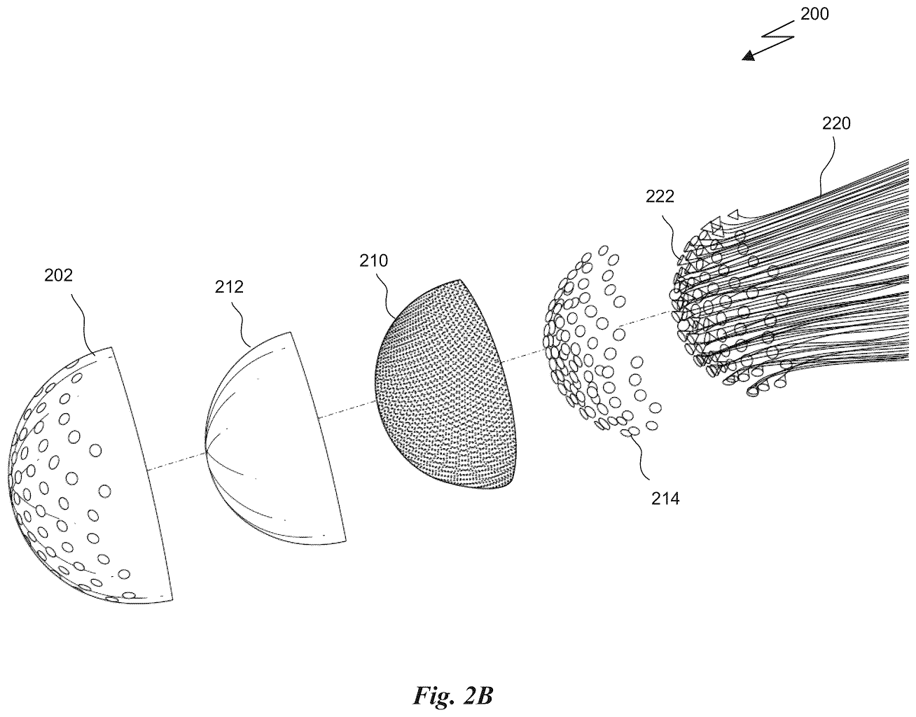

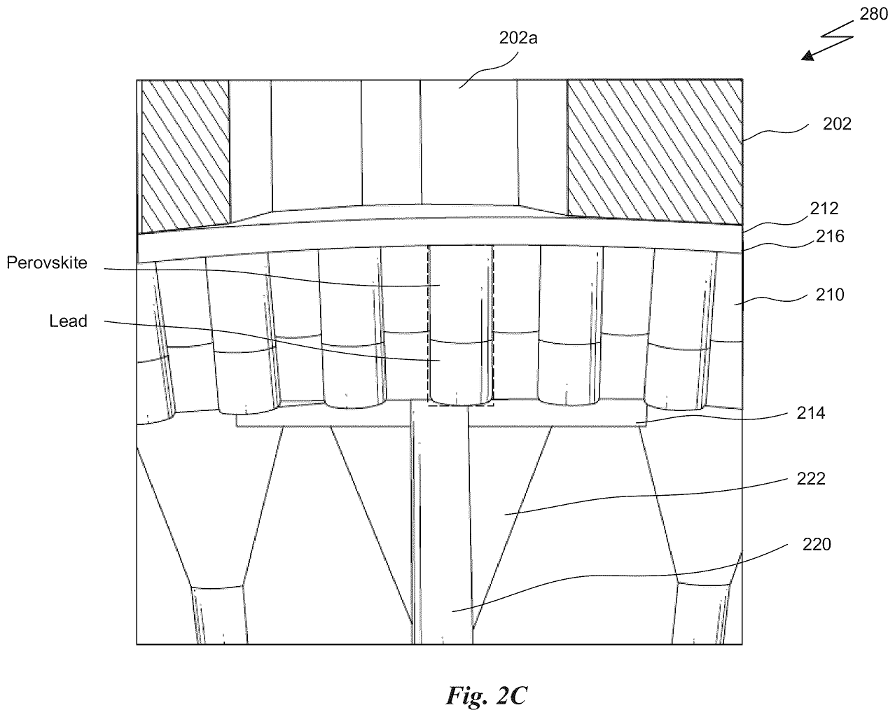

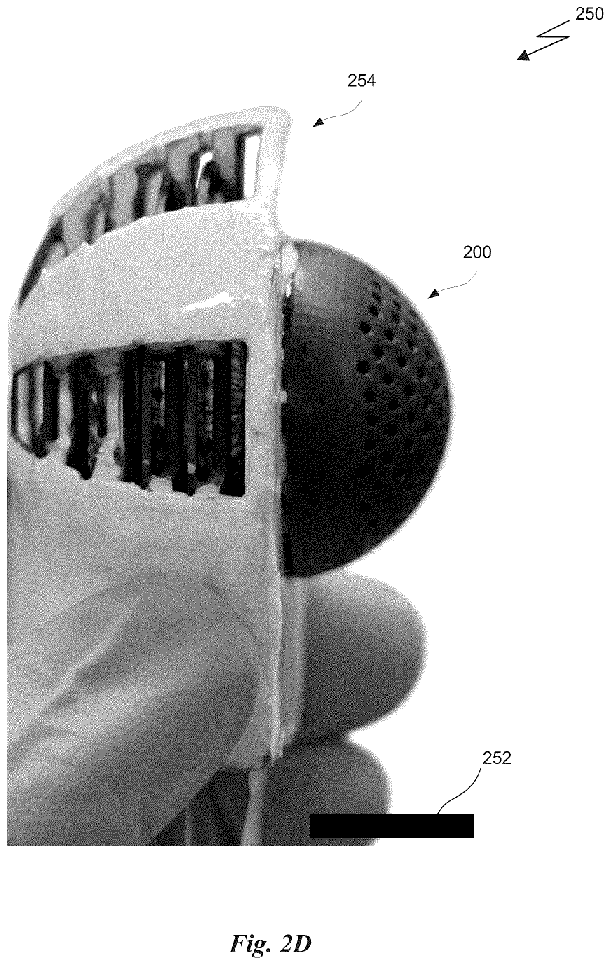

FIG. 2A illustrates an exemplary PHCE device 200, in accordance with one or more exemplary embodiments of the present disclosure. FIG. 2B is an exploded view of the PHCE device 200 of FIG. 2A. The device 200 is an exemplary implementation of the PHCE system 110 as depicted in FIG. 1B, which may be further integrated in the vision system 100 as depicted in FIG. 1A.

The device 200 includes two primary components, namely a pinhole array (PHA) and a NW array. The PHA includes a plurality of pinholes (e.g., 204) distributed along a curved surface. As shown in FIGS. 2A and 2B, the outermost layer of the device 200 is a hemispherical structure 202, which is distributed with the array of pinholes. In some embodiments, the hemispherical structure 202 with the PHA may be 3D-printed. However, it will be noted that other techniques may be employed to fabricate a hemispherical structure 202 with a PHA for suitable applications. In this example. The PHA serves as lensless optical channels, permitting controlled light rays to traverse through the small apertures (e.g., the pinholes) to proceed to the sensing elements of the detector (e.g., the NW array imager 130).

The NW array, along with other components, forms an imager (e.g., the NW array imager 130), which is positioned at or near the output of the PHA. The PHA aligns with the NW array imager, so that the light output from the PHA are detected by the nanowires within the NW array imager. In this configuration, the NW array is utilized to efficiently and effectively detect the light entering the PHCE device 200.

In some embodiments, the NW array includes an array of perovskite nanowires (PNA). Referring to FIG. 2B, the PNA is grown inside a hemispherical porous alumina membrane (PAM) template 210. The PAM template 210 includes an array of pores, where each pore is utilized to grow a corresponding perovskite nanowire. In other words, the perovskite nanowires are grown inside the pores of the PAM template 210. The PNA functions as an array of photoreceptors (e.g., the photoreceptors 132 as illustrated in FIG. 1B). In further embodiments, in each pore, the respective perovskite nanowire is grown on a residual nanowire. The residual nanowire is made of suitable metallic material, such as lead (Pb). As such, the nanowire array includes the PNA and a corresponding array of Pb nanowires in a heterostructure. The residual Pb nanowires are connected with metal wires, such as copper wires, facilitating the transmission of the generated signals from the NW array imager 130 to the control circuitry 140. This way, the visual information detected by the PHCE system 200 may be processed and visualized by a processer (e.g., within the control circuitry 140 of the PHCE system 110 and/or the computing system 150 of the vision system 100). With that said, the residual Pb nanowires function similarly to visual nerves. In some embodiments, each residual nanowire may be connected with one or more metal wires. Additionally and/or alternatively, multiple residual nanowires may be connected with a single metal wire. Accordingly, the PNA may be connected with the metal wires through the residual nanowires in a one-to-one, one-to-many, and/or many-to-one correspondences.

The nanowires within the PAM template 210 are connected to electrodes on both ends to form closed circuits, facilitating the transmission of signals to the control circuitry 140. As shown in FIG. 2B, an Indium Tin Oxide (ITO) thin film layer 212 may be fabricated on the convex surface of the PAM template 210, serving a common electrode. However, it will be noted that alternative materials with high electrical conductivity and optical transparency, similar to ITO, may be utilized as the electrode disposed between the PHA optical structure 202 and the PAM template 210. On the other hand, a plurality of metal contacts, such as Indium contacts 214, may be arranged on the concave surface of the PAM template 210. For example, the Indium contacts 214 may be fabricated on or attached to the concave surface of the PAM template 210. The Indium contacts 214 on the concave surface of the PAM template 210 may be paired with metal contacts (e.g., Gallium 222) on one end of the copper wires 220. In this configuration, the copper wires 220 are electrically connected to the PNA through the pairs of Indium contacts 214 and Gallium contacts 222. In some examples, one pinhole in the PHA structure 202 is aligned with one indium contact 214, which is referred to as an indium electrode pixel 214. Additionally, each indium electrode pixel 214 is aligned with a group of nanowires in the PAM template 210. In some instances, one pinhole in the PHA structure 202 is aligned with a group of indium electrode pixels 214, and each pixel 214 is aligned with one or more nanowires in the PAM template 210.

FIG. 2C provides a magnified cross-section view of a boxed section 280 depicted in FIG. 2A. As shown in FIG. 2C, starting from the outer layer and moving inwards (e.g., from top to bottom), the device 200 includes the PHA structure 202, a common electrode 212, perovskite and Pb nanowires within the PAM template 210, indium contacts 214, gallium contacts 222, and copper wires 220 with gallium contacts 222 wrapping around their respective ends. Additionally, a passivator layer 216 may be made between the common electrode 212 and the PNA within the PAM template 210. The passivator layer 216 may be used to prevent or inhibit unwanted chemical reactions or degradation at the interface between the common electrode 212 and the perovskite nanowires. The passivation materials may include silicon nitride (Si₃N₄), silicon dioxide (SiO₂), various organic polymers, and more. As shown in this example, a single pinhole 202a may be aligned with multiple nanowires (e.g., in the PAM template 210). However, it will be noted that other configurations may be adopted in various usage scenarios. For example, each pinhole 202a may be aligned with a single nanowire. Alternatively, each pinhole 202a may be aligned with a specific number of nanowires. The number of nanowires aligned with different pinholes may vary or remain consistent.

FIG. 2D is a side-view photograph 250 of a PHCE system mounted on printed circuit board 254. The PHCE system may include the device 200 as depicted in FIGS. 2A-2C. The scale bar 252 is one centimeter. This PHCE system 250 is designed with 121 ommatidia, which correspond to the pinholes in the PHA of the PHCE system 250. In this example, the ommatidia and the pinholes in the PHA are in a one-to-one correspondence, which each pinhole corresponds to one or more receptors and visual nerves (e.g., one or more nanowires in the nanowire array).

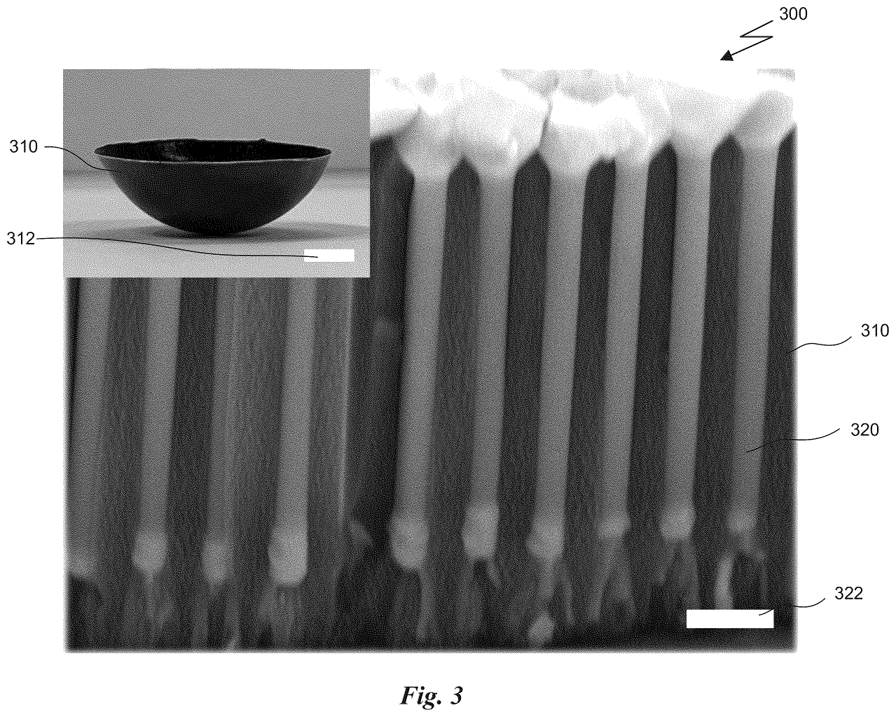

FIG. 3 is a scanning-electron microscope (SEM) image 300 of a hemispherical PAM 310 grown with nanowires 320. The PAM 310 with nanowires 320 may be employed as the PAM template 210 grown with nanowires in the device 200 as depicted in FIGS. 2A-2D, or as an intermediate product during the fabrication process of the PAM template 210 for the device 200. The scale bar 322 for the SEM image 300 is one micrometer. Inset shows a SEM image of the hemispherical PAM 310, where the scale bar 312 is five millimeters.

As shown in FIG. 3, the nanowires 320 includes different sections, such as perovskite nanowire sections and residual nanowire sections. With this design, the perovskite nanowires inside the PAM 300 have a pitch of approximately 500 nm and a diameter of approximately 300 nm, indicating a uniform alignment with high density.

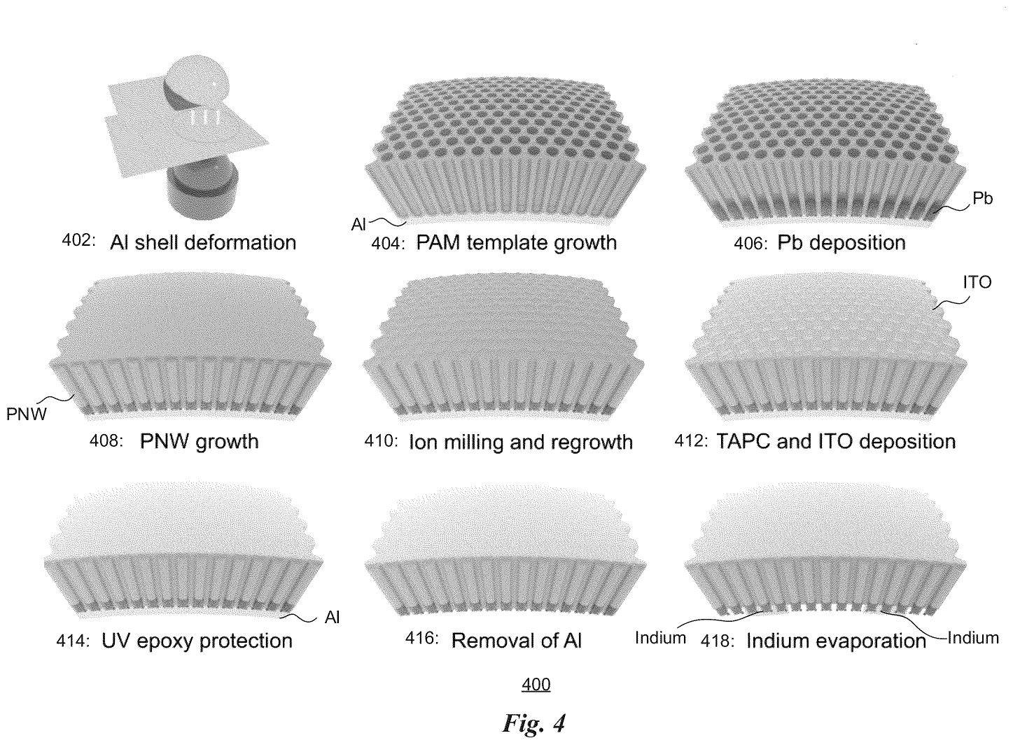

FIG. 4 is a process flow 400 for fabricating a NW array detector, in accordance with one or more exemplary embodiments of the present disclosure. By performing the process flow 400, an NW array detector having a spherical structure may be fabricated. The resulting NW array detector may be situated underneath a PHA (e.g., the PHA 120 in the PHCE system 110 illustrated in FIG. 1B and/or in the device 200 depicted in FIGS. 2A-2D) to function as the NW array imager 130 of the PHCE system 110. The NW array detector may be connected to and controlled by the control circuitry 140 of the PHCE system 110.

At 402, an aluminum (Al) shell is deformed to form a hemispherical substrate.

At 404, a hemispherical porous alumina membrane (PAM) template is made on the deformed Al shell from process 402. For example, alumina may be grown on the Al shell by anodic oxidation to form a honeycomb structure along a normal direction to the hemispherical surface of the Al shell. However, it will be noted that various alternative techniques may be applied to create the PAM template, including molding, drilling, mechanical or laser cutting, etc. The honeycomb structure provides an array of vertical nanowire structures (e.g., pores) along the hemispherical surface corresponding to the Al shell. This way, the PAM template provides innate encapsulation for perovskite materials, elevating the operational performance.

At 406, a Pb layer is deposited on the Al shell and within the nanowire structures of the PAM. The Pb layer within the pores of the PAM templates for an array of residual nanowires as the visual nerves 134 discussed above. Additionally and/or alternatively, the Pb residual nanowires on the Al shell may serve as a seed layer for the subsequent growth of perovskite nanowires within the PAM template.

At 408, a perovskite nanowire (PNW) array (PNA) is grown on the array of Pb residual nanowires within the pores of the PAM. The Pb residual nanowires and/or the perovskite nanowires may be grown using various techniques, such as chemical vapor deposition (CVD), molecular beam epitaxy (MBE), atomic layer deposition (ALD), thermal evaporation, solution-phase synthesis, or other techniques.

At 410, ion milling is applied to expose the top surface of the PAM template, revealing the grown nanowires spaced along the vertical walls of the honeycomb structure of the PAM template.

Additionally, a regrowth process may be applied to further repair the properties of the grown nanowires which may be damaged in the ion milling process. In the regrowth process, the nanowires that have already been synthesized serve as substrates or templates for further growth. The same perovskite material or the precursor is then deposited onto the surface of these nanowires using various techniques such as chemical vapor deposition (CVD), molecular beam epitaxy (MBE), solution-phase synthesis, or the like.

At 412, a passivation layer and common electrode on top of the PNA are fabricated. For example, the passivation material(s) and electrode material(s) may be deposited on top of the exposed surface from 410. The passivation material and the electrode material may be TAPC (which stands for Di-[4-(N,N-ditolyl-amino)-phenyl] cyclohexane) and ITO.

At 414, a protective coating is applied for ultraviolet (UV) epoxy protection, for example, by using UV curable epoxy resin.

At 416, the Al shell is removed from the bottom of the PAM template. The Al substrate may be removed through various techniques, such as wet etching, dry etching, milling, grinding, laser ablation, etc. As a result, the bottom surface of the PAM template and the Pb residual nanowires within the pores of the PAM template are exposed.

At 418, Indium may be deposited on the exposed bottom surface of the PAM template according to a predefined pattern. As such, a plurality of Indium contacts may be fabricated on the Pb residual nanowires. The deposition of the Indium may be performed by evaporating an Indium source. The deposited Indium may form a plurality of Indium contacts according to a predefined pattern (e.g., by applying a suitable mask).

In some embodiments, the perovskite nanowires grown in 408 and/or during the regrown in 410 may be engineered to achieve varying detection ranges. For example, the composition of the perovskite nanowires include halide and metal elements. During the deposition process (e.g., CVD), the halide and metal elements, such as their concentrations, in the perovskite nanowires may be controlled. The resulting PNA may exhibit sensitivity to different ranges of spectra.

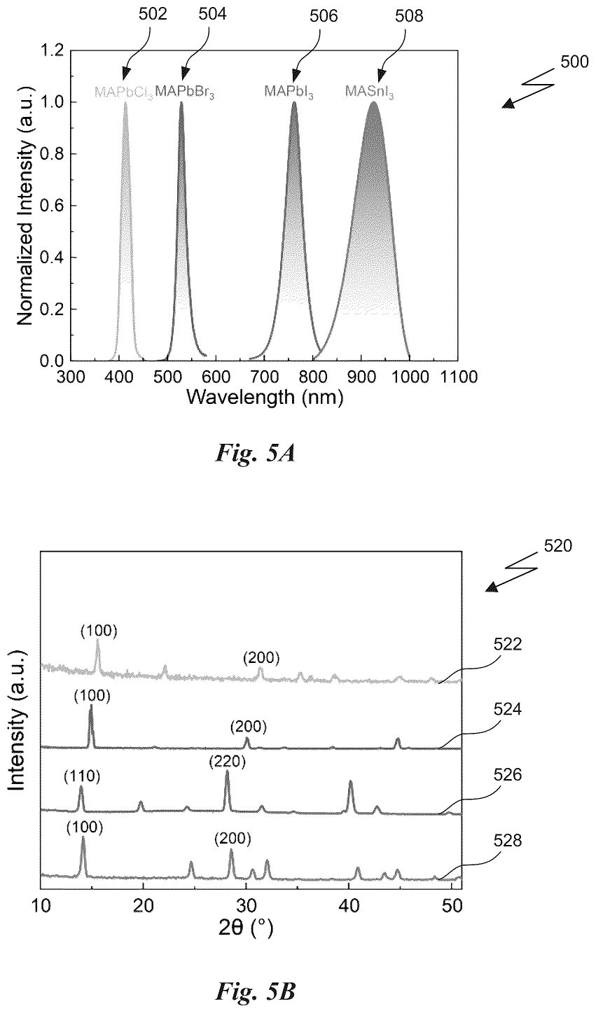

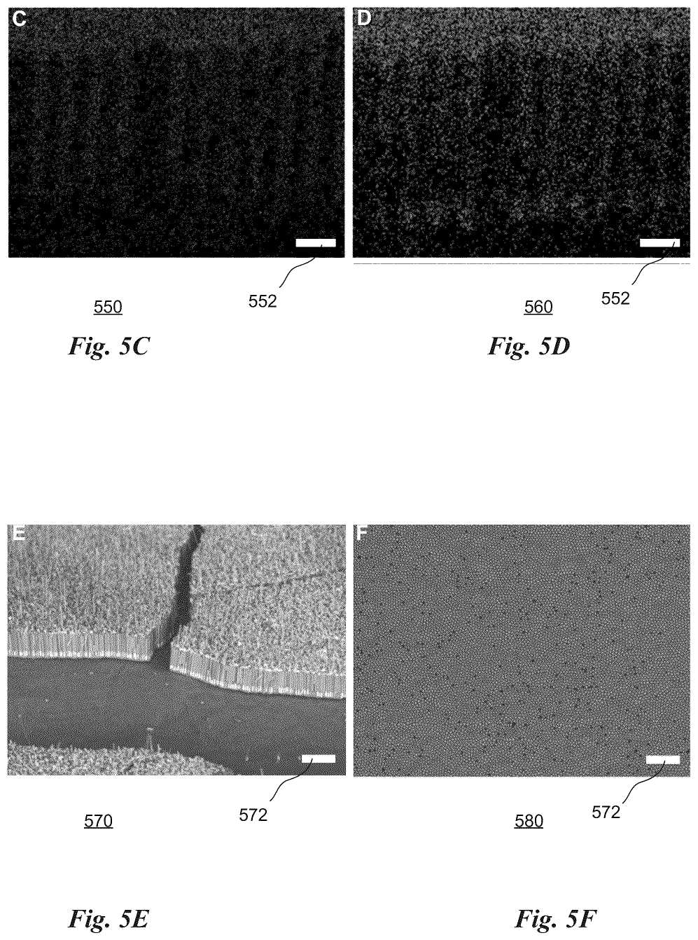

FIGS. 5A-F are characteristics of various perovskite materials. The characteristics demonstrate that a PNA photodetector made of a PNA may sense light from visible to near-infrared region. As shown in FIG. 5A, different perovskite materials exhibit variable peaks (e.g., peaks 502, 504, 506, and 508) in the photoluminescence spectra 500. For example, Methylammonium lead chloride (MAPbCl₃) (e.g., peak 502) and Methylammonium lead bromide (MAPbBr₃) (e.g., peak 504) exhibit sensitivities to different regions within the visible spectrum, which spans roughly from 400 nanometers to 700 nanometers. Methylammonium lead triiodide (MAPbI₃) (e.g., peak 506) exhibits sensitivity to both visible and infrared regions, while Methylammonium tin iodide (MASnI₃) (e.g., peak 508) exhibit sensitivity to a region within the infrared spectrum. The infrared spectrum extends beyond approximately 700 nanometers.

FIG. 5B is an X-ray diffraction (XRD) spectra 520 of different perovskite nanowires inside a PAM template. The perovskite nanowires are grown inside a PAM template made of Anodic Aluminum Oxide. The x-axis represents the diffraction angle, where 2θ is the angle between the incident X-ray beam and the diffracted X-ray beam. Peaks labeled with “100” are associated with diffraction from the (100) crystallographic plane, while labeled with “200” are associated with diffraction from the (200) crystallographic plane. As shown in FIG. 5B, diffraction peaks of well-crystalline perovskites shift with the substituted elements. The diffraction peaks 522, 524, 526, and 528 correspond to MAPbCl₃, MAPbBr₃, MAPbI₃, and MASnI₃ nanowires, respectively.

FIGS. 5C and 5D are plots (550 and 560) of elemental analysis of perovskite nanowires. These characterizations show the growth results, such as morphology, composition, fill ratio, of nanowires. The scale bar 552 in the plots 550 and 560 is one micrometer. The elemental analysis as shown in FIGS. 5C and SD confirms the uniform growth of PNA.

In the present disclosure, MAPbI₃ is utilized as the photosensitive material for the PNA in the devices/systems to illustrate the structure and/or operation of these devices/systems for illustrative purposes only. As shown in FIGS. 5A and 5B, MAPbI₃ may encompass the entire visible wavelength range. However, it will be noted that other suitable perovskite materials may be utilized in these devices/systems for other suitable applications.

By tuning the PAM thickness and growth conditions, well-crystalline MAPbI₃ nanowires with a high filling ratio (>95%) inside PAM may be obtained. FIGS. 5E and 5F are SEM images (570 and 580) of MAPbI₃ nanowires grown inside the PAM. The SEM images 570 and 580 are in side view and top view, respectively, where the scale bar 572 is three micrometers.

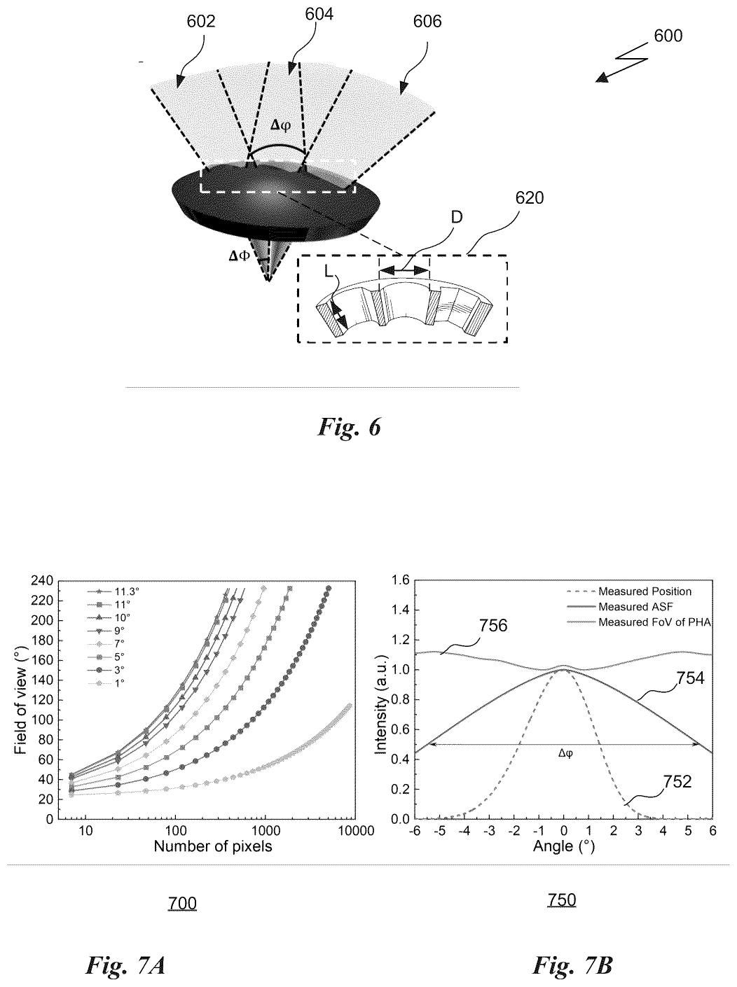

FIG. 6 is an exemplary layout 600 of the pinholes in the PHA, in accordance with one or more exemplary embodiments of the present disclosure. The pinhole layout 600 may be applied to the PHA in any of the devices/systems provided in the present disclosure. For example, the pinholes, such as pinholes 602, 604, and 606, may be part of the PHA within the PHCE system, as shown in FIG. 2D.

As mentioned above, the PHA is designed in honeycombed structure, such that the pinholes 602, 604, and 606 are distributed along a curved structure. FIG. 6 illustrates a set of parameters corresponding to the design of the pinholes, including the diacritical acceptance angle (Δφ), the interommatidial angle (ΔΦ), a diameter (D), and a length (L) (in the dashed box 620) of each pinhole. The set of parameters are related to various optical aspects of the optical system, such as FOV, blind zone, and other characteristics.

As shown in FIG. 6, light passing through the pinholes 602, 604, and 606 may converge to a spot on the PHA, which is beneath the central pinhole 604. As such, a pinhole may correspond to a pixel of the NW array imager. The converged light may be detected by one or more nanowires (e.g., the photoreceptors) in the PNA. To this end, light passing through the PHA may be detected by a plurality of pixels of the NW array imager.

For each pinhole, the diacritical acceptance (Δφ) refers to the angular range within which the respective pinhole may effectively accept incident light or radiation. In other words, the diacritical acceptance (Δφ) represents the acceptance angle of the incident light/radiation for a specific pinhole. The interommatidial angle (ΔΦ) refers to the angle between adjacent ommatidia (e.g., the pinholes). For example, the interommatidial angle (ΔΦ) indicates the angular deviation between the central axes of two adjacent pinholes. In some embodiments, Δϕ is slightly larger than ΔΦ, so that the blind zone of the optical system may be optimized.

FIGS. 7A and 7B are characteristics of the PHA, in accordance with one or more exemplary embodiments of the present disclosure. Plot 700 in FIG. 7A demonstrates simulation of integral FOV as a function of the number of pinhole pixels with different interommatidial angles (ΔΦ). The simulation is performed on a PHCE system with 121 ommatidia, a L/D ratio of five and a diacritical acceptance angle (Δφ) of 11.3°. As indicated by plot 700, the PHCE system with 121 ommatidia may achieve a total FOV of approximately 143°, when Δφ and ΔΦ are equal to 1.3° and 10°, respectively.

Plot 750 in FIG. 7B shows measurement results of light intensity distribution. In this example, dashed curve 752 represents the measured positions in angles relative to a surface normal associated with a respective pinhole (e.g., the pinhole 604 in FIG. 6). Curve 754 represents the measured angular selective function (ASF) based on the measured positions indicated by the dashed curve 752. The ASF indicates light distribution after the light passing through a single pinhole. As shown in FIG. 7B, the diacritical acceptance (Δφ) may be defined based on the half-intensity point according to the measured ASF for the respective pinhole (e.g., curve 754). Curve 756 represents the overall intensity distribution (e.g., with light contributions from three pinholes) measured at the positions according to the dashed curve 752. The curve 756 indicates the FOV of the PHA at the respective pinhole. In some examples, a light-absorbing resin may be used for printing to thwart light scattering among adjacent pixels.

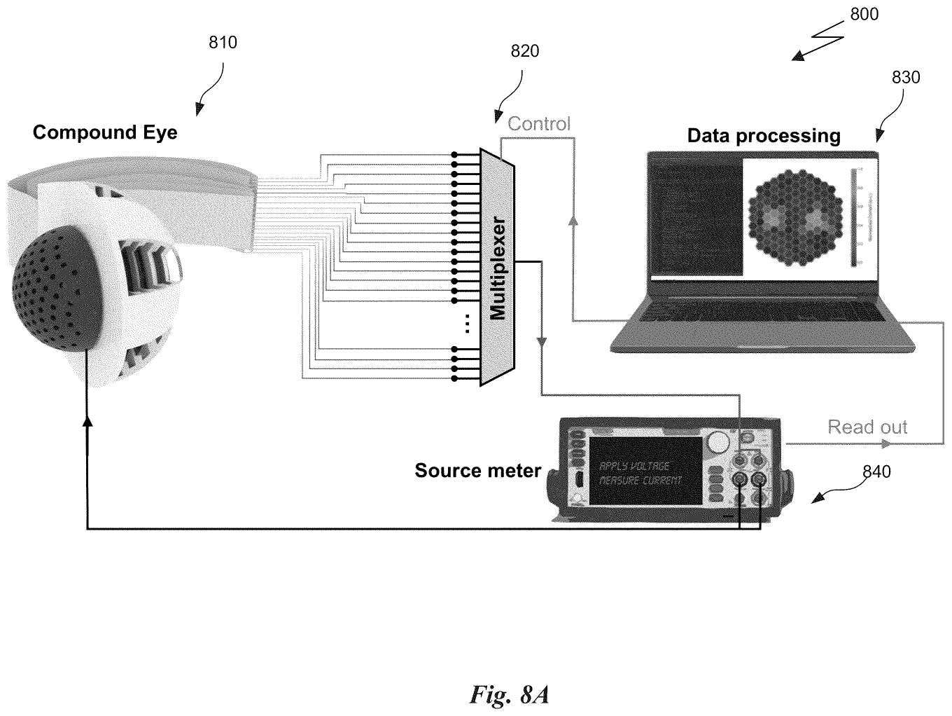

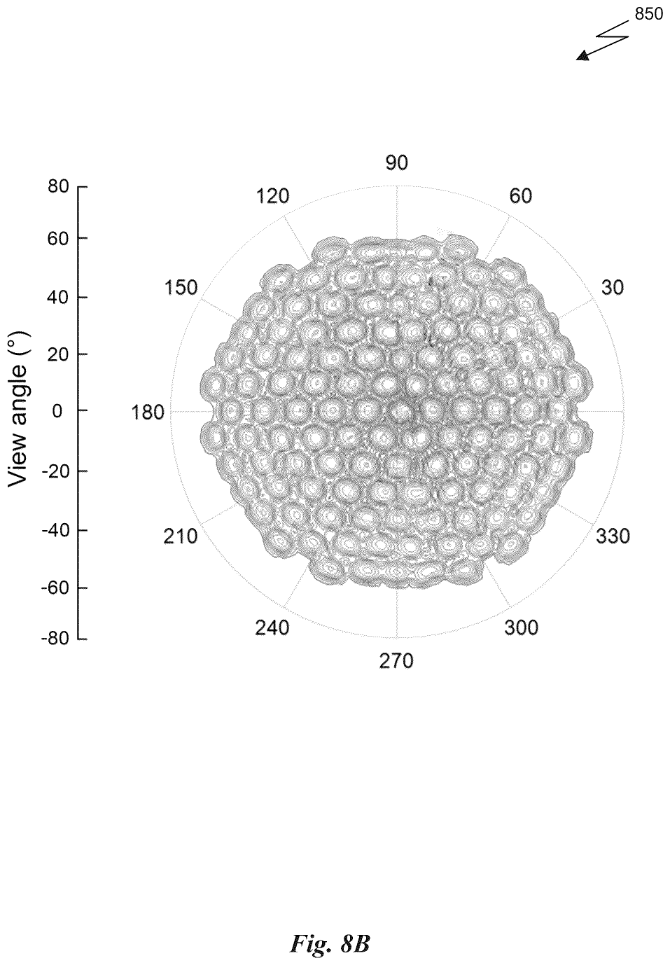

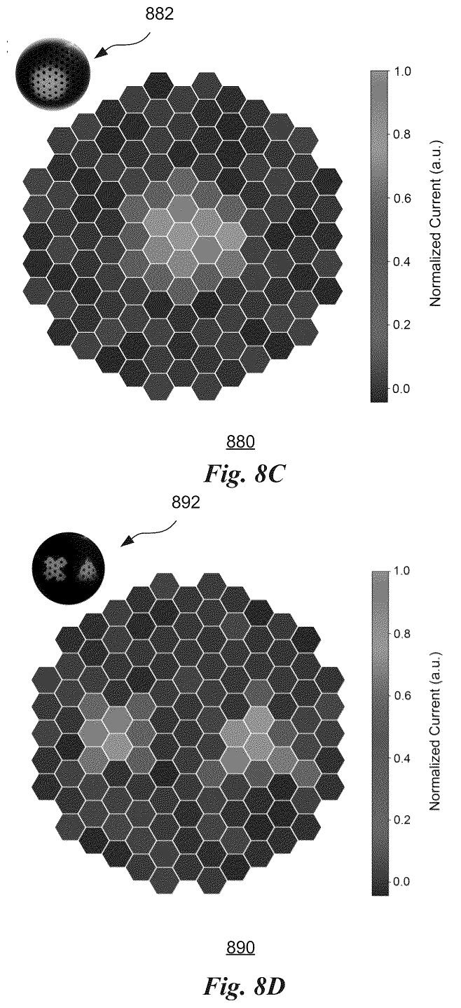

FIG. 8A illustrates an exemplary measurement setup 800 for a monocular vision system 810, in accordance with one or more exemplary embodiments of the present disclosure. The measurement setup 800 connects the monocular vision system 810 to a computing system 830 and a power source and source meter 840, through a switching device 820. It will be noted that other arrangements may be implemented, for example, the switching device 820, the power source and source meter 840, and/or some or all of the functional modules within the computing system 830 may be integrated in the monocular vision system 810.

The monocular vision system 810 includes a compound eye (CE) with a pinhole array (PHA). As shown in FIG. 8A, the PHA of the monocular vision system 810 is exposed and positioned to capture incident light. A NW array imager and suitable circuits may be located within the enclosed space confined by the spherical PHA structure and a housing attached thereto. The monocular vision system 810 is powered by the power source 840, facilitating the acquisition of the signals generated from the monocular vision system 810. The switching device 820 may include a multiplexer, a switching network, and/or other appropriate switching devices, enabling the signals associated with multiple pixels from the monocular vision system 810 to be recorded by source meter 840 and further transmitted to the computing system 830 sequentially, in parallel, or through a combination thereof. In this example, the monocular vision system 810 includes a total of 121 ommatidia to collect vision information. The 121 ommatidia (e.g., the corresponding photoreceptors and visual nerves) are connected to a computer-controlled multiplexer (e.g., the switching device 820) via printed circuit boards (within the monocular vision system 810).

The computing system 830 is an example of the computing system 150 as depicted in FIG. 1C. The computing system 830 implements one or more interfaces of the UI 180 as depicted in FIG. 1D. The computing system 830 may process the signals associated with the light captured by the monocular vision system 810 to reconstruct a capture pattern and display it in the UI 180.

FIG. 8B is an exemplary visualization of the measurement result of field of view 850, in accordance with one or more exemplary embodiments of the present disclosure. The pattern 850 is obtained based on the signals from the monocular vision system 810 by employing the measurement setup 800 as depicted in FIG. 8A. The measurement result 850 shows the intensity distribution across the hemispherical imaging system. Based on the measurement result 850, the areas containing pinholes show higher light intensity, whereas the regions between the pinholes exhibit lower light intensity. The hemispherical geometry endows the entire system with a large FOV. As depicted in FIG. 8B, the overall visual field of the hemispherical PHCE (e.g., the monocular vision system 810) is approximately 140°, which is well consistent with the abovementioned simulation results as illustrated in FIG. 7A.

FIGS. 8C and 8D are visualizations of exemplary patterns captured by the monocular vision system 810 with the measurement setup 800 as demonstrated in FIG. 8A. Insets 882 and 892 provide the optical photos of patterns. The light source used for imaging is convergent light.

As shown in FIG. 8C, the visualization 880 demonstrates a circular pattern captured by the monocular vision system 810, aligned with the pattern indicated in inset 882. As shown in FIG. 8D, the visualization 890 demonstrates a cross and a triangular patterns captured by the monocular vision system 810, aligned with the patterns indicated in inset 892.

In these visualizations, the pixels are represented by hexagonal units. The pattern projected onto the surface of the monocular vision system 810 may form a corresponding distribution of light intensity on the detector (e.g., the NW array imager). The resulting visualized pattern reflects both the shape of the projected pattern and the distribution of light intensity. In some examples, the light intensity of each pixel may be associated with a current value readout from the respective pixel.

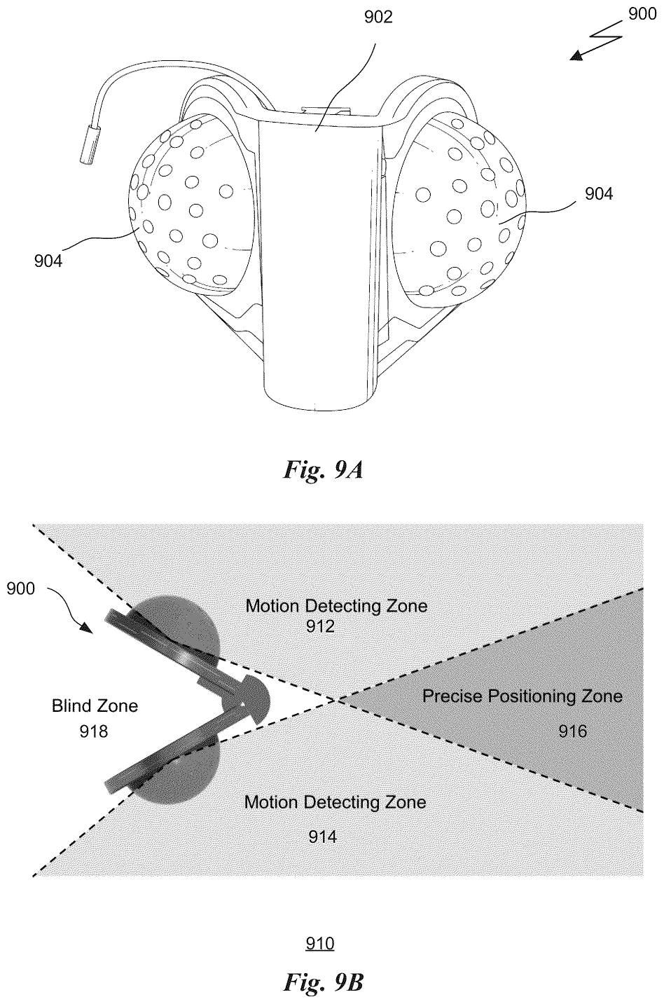

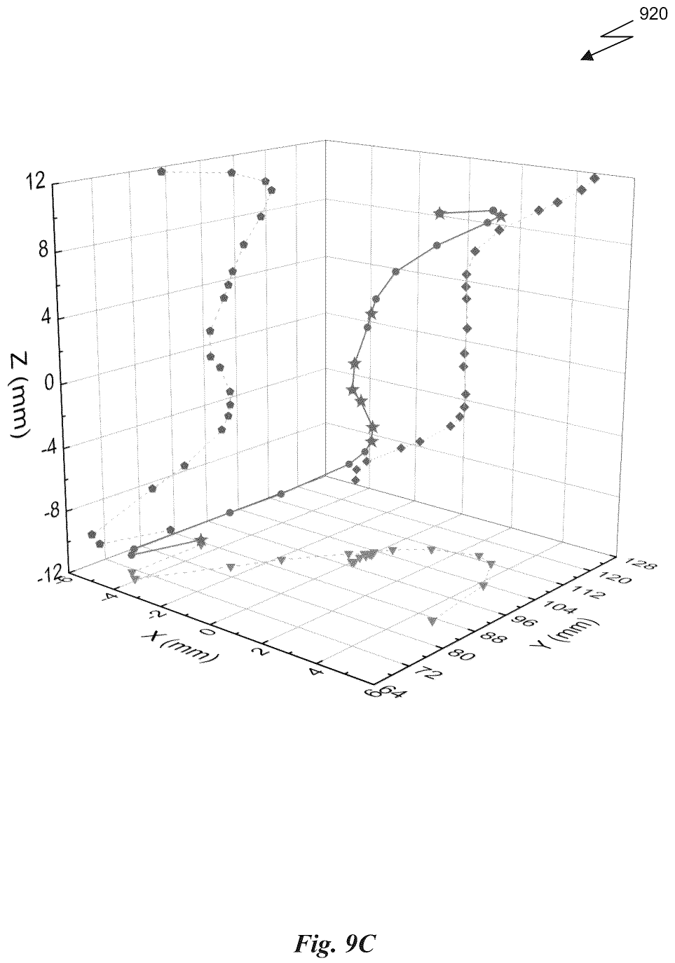

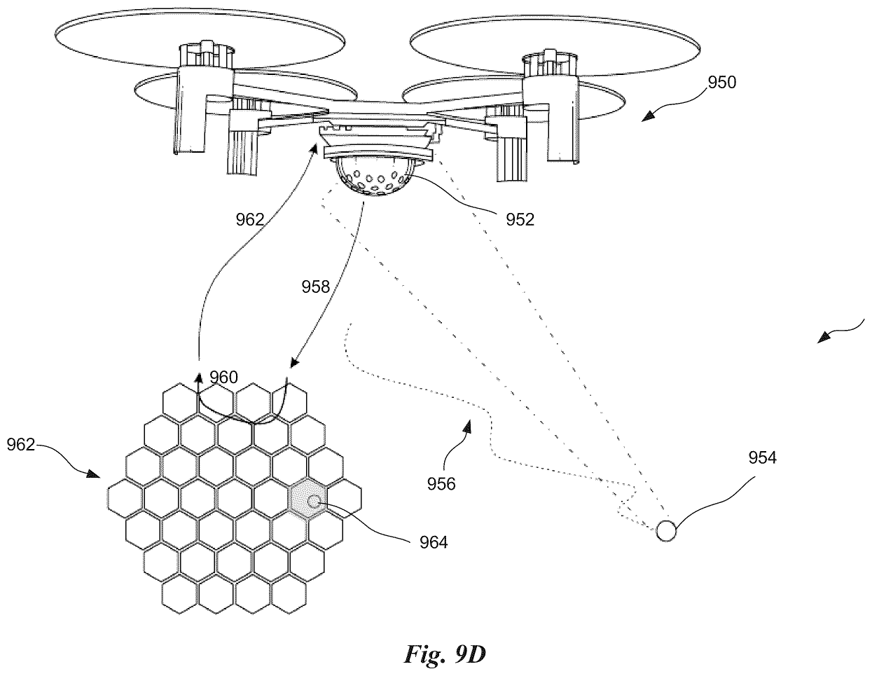

FIG. 9A shows an exemplary binocular vision system 900, in accordance with one or more exemplary embodiments of the present disclosure. The dimensions of the binocular vision system 900 may be on the order of a few centimeters. As depicted in FIG. 9A, the binocular vision system 900 includes a pair of PHCE systems 904 mounted on a frame 902. The PHCE systems 904 may utilize the PHCE system 110 depicted in FIG. 1B, which may be an example of the vision system 100 as illustrated in FIG. 1A. As shown in FIG. 9A, the pair of PHCE systems 904 is fixed onto the frame 902, where these two PHCE systems 904 are configured to detect vision information from different angles. The binocular vision system 900 may be integrated with integrated circuits for onboard signal collecting, processing, and wireless communication.

In this embodiment, each PHCE systems 904 in the binocular vision system 900 is designed with 37-ommatidia, corresponding to 37 pixels. The pinholes in the PHA are designed with a L/D ratio of 2.5, and the angle ΔΦ is designed to be 20°. A point light source is used as an object. With a single PHCE, when the point light source moves away from the PHCE, the illuminated area on the respective PHCE will increase, and more pixels will be activated, and vice versa. Moreover, when the point source moves towards other directions, the synclastic pixels will respond. Synclastic pixels refer to pixels along the same direction of movement on the curved surface. To accurately position a 3D moving trajectory of a point source, a dual-eyed system, such as the binocular vision system 900 as depicted in FIG. 9A, may be constructed.

FIG. 9B illustrates the working principle of a binocular vision system, in accordance with one or more exemplary embodiments of the present disclosure. The binocular vision system may be embodied as the binocular vision system 900 of FIG. 9A.

As outlined above, each PHCE system 904 has an ultra-wide FOV, approximately a near panoramic visual field. A single compound eye uses a motion parallax technique to determine the position of objects in its surroundings. Motion parallax relies on the movement of the observer to provide depth perception. As the observer (e.g., a CE) moves, objects at different distances will appear to move across the compound eye at different rates. Objects closer to the observer will appear to move more quickly across the eye, while objects farther away will appear to move more slowly. By comparing the relative motion of objects across the compound eye, the distances and positions of the objects may be determined.

A pair of compound eyes have binocular vision, enabling the perception of depth and distance through stereopsis—the slight differences in the images captured by each eye. This allows for more precise depth perception and spatial awareness.

In this example, the entire zone of the vision system 900 is divided into three parts, namely, blind zone 918, motion detecting zone 912, 914, and precise positioning zone 916. As shown in FIG. 9B, the FOV of each PHCE system 904 is associated with a respective motion detecting zone 912 or 914, while the overlapping portions of the FOV of the two PHCE systems 904 constitute a precise positioning zone 916. The regions outside the FOV of the two PHCE systems 904 constitute the blind zone 918.

In an exemplary setup, the angle between the two PHCEs of the binocular vision system 900 is fixed to 60°, as such the overall FOV of the binocular system 900 is increased to 220°. The binocular vision system 900 is connected to a computer-controlled multiplexer (e.g., a switching device) and the real-time data is collected via programming. Measurements are taken by randomly moving a point source in the positioning zone and recording nodes with the binocular vision system 900.

FIG. 9C shows calculated spatial positions and generated movement paths based on measurements taken by the binocular vision system 900. This verifies the target positioning capability of a PHCE system.

In an embodiment, a monocular vision system (e.g., integrated with a single PHCE) with integrated circuits is utilized for onboard signal collecting, processing, and wireless communication. FIG. 9D illustrates the working principle of on-drone motion tracking, in accordance with one or more exemplary embodiments of the present disclosure. As shown in FIG. 9D, a single PHCE 952 (e.g., the PHCE system 200 in FIGS. 2A-2D, or the monocular vision system 810 in FIG. 8A) is mounted on a drone 950. The drone 950 is integrated with a control unit (e.g., a processor) for signal processing. In some examples, the control unit may be integrated into or in communication with a computing system (e.g., the computing system 150 as depicted in FIG. 1C) that is configured to process the data acquired by the PHCE system and generate instructions to control the operation of the drone 950. However, it should be noted that other configurations may be adopted. For example, a binocular system (e.g., the binocular vision system 900 in FIGS. 9A-9B) may be mounted on the drone 950. As indicated in FIG. 9B, the FOV of the single PHCE 952 constitutes the motion detecting zone.

As shown in FIG. 9D, light from a target 954 is detected by the PHCE 952. For example, the target 954 may be treated as a light source. The target 954 moves along a trajectory, as indicated by dashed line 956. The PHCE 952 senses the light signal in the FOV of the PHCE 952, as indicated by arrow 958. The PHCE 952 transmits the detected signal to the control unit on the drone for signal processing. The control unit processes the data from the PHCE 952, as indicated by arrow 960. For example, the control unit reconstructs the captured images in a suitable visualization 962 (e.g., in the UI 180 as illustrated in FIG. 1D). The position of the target 954 may be indicated by spot 964, which exhibits a high intensity of light. The reconstructed images indicate the position and/or motion of the target relative to the PHCE 952 (or the drone 950). Subsequently, the control unit provides one or more movement instructions to the drone 950, as indicated by arrow 962. For example, the one or more instructions may cause the drone 950 to track the target 954 during its movement and/or to adjust the pose/position of the drone 950 to capture additional images from other perspectives. This system exhibits excellent angular selectivity.

In a further embodiment, the target 954 is a quadruped robot mounted with a point light source. By performing the processes as illustrated in FIG. 9D, the control unit gives movement instructions to the drone 950 according to the relative position change between the drone 950 in the air and the quadruped robot 954 on the ground. The PHCE 952 captures images with a frame rate of approximately 25 Hz, in accordance with the response time of the PNA detector. The flight of the drone 950 is controlled by a tunable proportional, integral, and derivative (PID) algorithm.

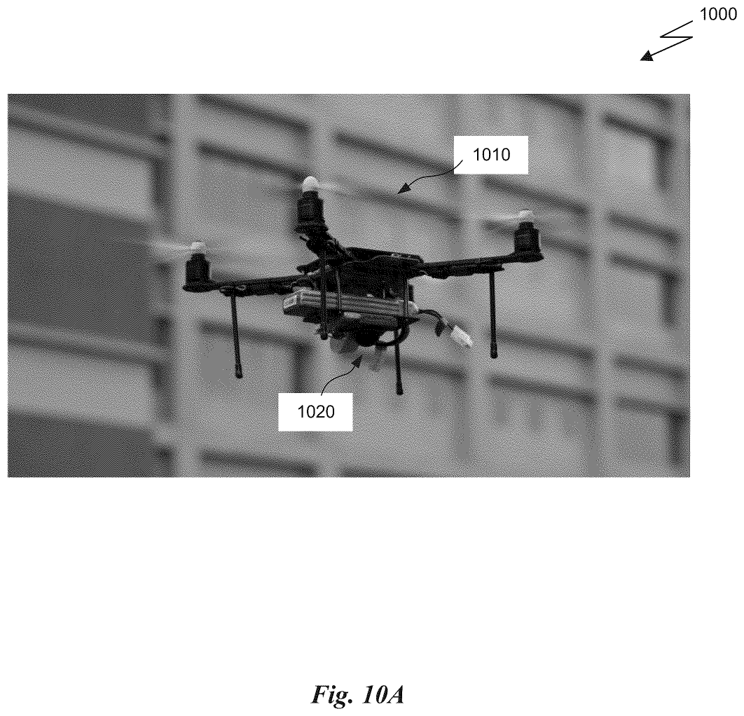

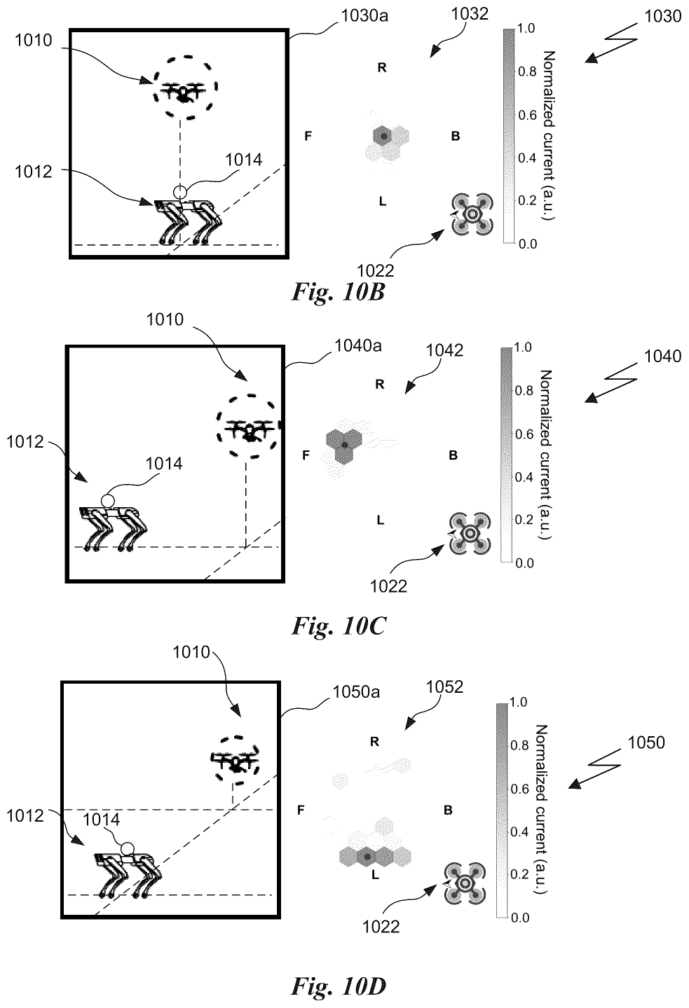

FIG. 10A is a photograph 1000 of a drone 1010 integrated with a PHCE system 1020, in accordance with one or more exemplary embodiments of the present disclosure. The PHCE system 1020 is fixed by a 3D-printed holder. The drone 1010 with integrated PHCE 1020 has successfully tracked the continuous motion of a quadruped robot 1012 (installed with a white light source 1014) along a square path. FIGS. 10B-10D include plots 1030, 1040, and 1050 comparing digital images (illustrated by line graphs 1030a, 1040a, and 1050a, respectively) with the current maps captured at different moments by the drone 1010 with the PHCE system 1020. The dashed lines in the line graphs 1030a, 1040a, and 1050a indicate relative spatial relationships between the drone 1100 and the quadruped robot 1012. As shown in FIG. 10B, when the drone 1010 is hovering over the quadruped robot 1012, the reconstructed image 1032 (e.g., the current map) indicates that the target (e.g., the light source mounted on the quadruped robot 1012) is at the center of the FOV of the PHCE system 1020. Similarly, the reconstructed images 1042 and 1052 in FIG. 10C and FIG. 10D, respectively, indicate the location of the target in the FOV of the PHCE 1020 mounted on the drone 1010. The inset icon 1022 represents the forward direction of the drone 1010. F, B, R, and L represent front, back, right, and left, respectively. As such, the excellent consistency strongly substantiates the tracking accuracy and repeatability of this fully integrated system.

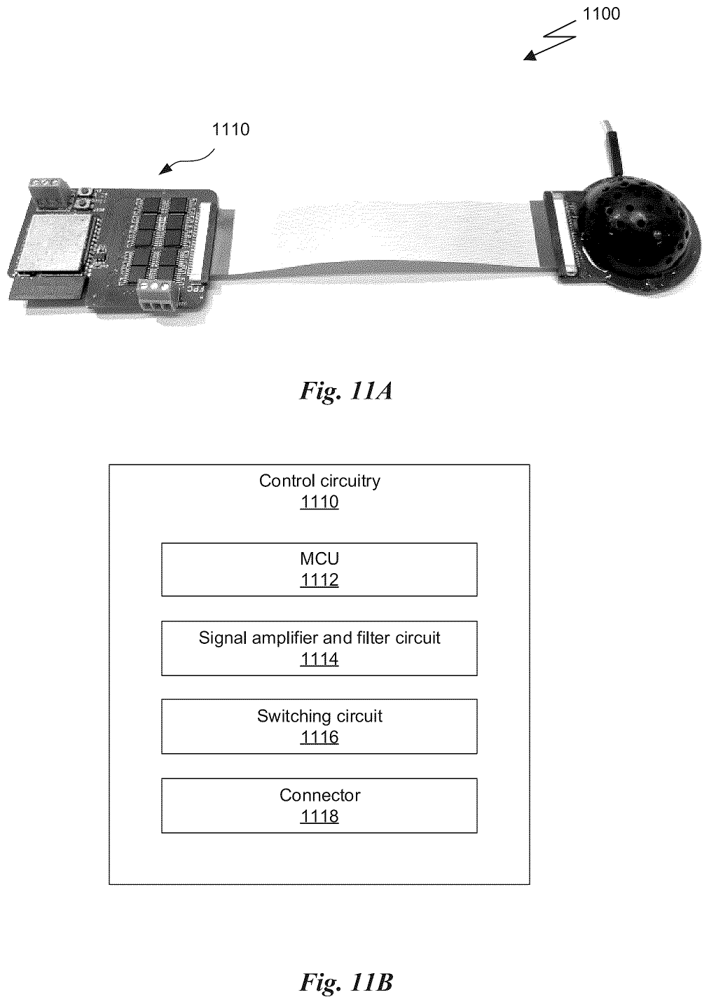

FIG. 11A is a photograph of the PHCE system 1100 with an example control circuitry 1110. The PHCE system 1100 may be integrated in the drone system as demonstrated in FIG. FIG. 10A. For example, the control circuitry 1110 may be in communication with the control unit of the drone 980. As shown in FIG. 11A, the control circuitry 1110 includes various electrical components and peripheral circuits integrated on an integrated circuit board (PCB). The PCB integrated with the circuitry 1110 is connected to the PHCE through a flex connector. However, it will be noted that other types of electrical connection may be adopted.

FIG. 11B is a block diagram illustrating various components in the control circuitry 1110. For example, the control circuitry 1110 may include a microcontroller unit (MCU) 1112, a signal amplifier and filter circuit 1114, a switching circuit 1116, and a connector 1118.

The MCU 1112 is configured to process the received signal and generate one or more instructions to facilitate any of the operations/functionalities disclosed herein.

The signal amplifier and filter circuit 1114 includes a selection of suitable amplifiers and filters to enhance the received signals from the PHCE. For example, the amplifiers may boost the input signals, while the filters may attenuate noise signals.

The switching circuit 1116 is controlled by the MCU 1112 to selectively obtain signals corresponding to specific pixels in a predefined sequence. The switching circuit 1116 may include various components, such as a multiplexer, crossbar switches, analog/digital switches, and the like.

The connector 1118 facilitates the connection to the PHCE. For example, the connector 1118 may be connected to wires extended from the visual nerves of the PHCE, thereby establishing data transmission channels between the control circuitry 1110 and the PHCE.

It is noted that the techniques described herein may be embodied in executable instructions stored in a computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic format. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods/processes described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

What is claimed is:

1. A pinhole compound eye (PHCE) system, comprising:
a pinhole array comprising a plurality of pinholes, wherein the pinhole array is configured to receive light from varying incident angles; and
a detector array comprising a plurality of nanowires, wherein the detector array is positioned at a concave surface of the pinhole array and is configured to detect light passing through the pinhole array.

2. The system according to claim 1, wherein the pinhole array is confined within a honeycombed hemispherical structure.

3. The system according to claim 2, wherein the honeycombed hemispherical structure with the pinhole array is 3D-printed.

4. The system according to claim 1, wherein the plurality of nanowires are inside a plurality of pores within a hemispherical membrane template.

5. The system according to claim 4, wherein the hemispherical membrane template is a hemispherical porous alumina membrane (PAM), and wherein each pore of the plurality of pores corresponds to a subset of nanowires of the plurality of nanowires.

6. The system according to claim 1, wherein each nanowire of the plurality of nanowires comprises a perovskite nanowire section and a residual nanowire section.

7. The system according to claim 6, wherein the perovskite nanowire sections are positioned proximate to the pinhole array, and the residual nanowire sections are connected to a control circuit.

8. The system according to claim 1, wherein each nanowire of the plurality of nanowires is aligned with a corresponding pinhole of the plurality of pinholes, and wherein each pinhole is associated with a pixel of the detector array.

9. The system according to claim 8, wherein the detector array comprises a plurality of pixels corresponding to the plurality of pinholes in the pinhole array, wherein the plurality of pixels are connected to a control circuit through a plurality of contacts, and wherein each pixel of the plurality of pixels corresponds to a contact of the plurality of contacts.

10. The system according to claim 8, wherein each nanowire is arranged to receive light from the corresponding pinhole and one or more adjacent pinholes of the plurality of pinholes.

11. The system according to claim 1, further comprising:
a control circuit connected to the detector array and configured to obtain detection results from the detector array, wherein the control circuit comprises a readout circuit configured to read values from the plurality of nanowires in the detector array based on the light detected by the plurality of nanowires.

12. The system according to claim 1, further comprising:
a second pinhole array comprising a plurality of pinholes distributed, wherein the second pinhole array is configured to receive light from varying incident angles;
a second detector array comprising a plurality of nanowires, wherein the second detector array positioned at a concave surface of the second pinhole array and configured to detect light passing through the second pinhole array; and
a frame, wherein the first pinhole array with the corresponding first detector array and the second pinhole array with the corresponding second detector array are mounted on the frame.

13. The system according to claim 12, wherein the first pinhole array with the corresponding first detector array corresponds to a first field of view, the second pinhole array with the corresponding second detector array corresponds to a second field of view, and the first field of view and the second field of view have an overlapping region.

14. A method for fabricating a pinhole compound eye (PHCE) system, comprising:
fabricating a hemispherical structure comprising a pinhole array with a plurality of pinholes distributed along a surface of the hemispherical structure;
fabricating a hemispherical membrane template comprising a plurality of pores distributed along a surface of the hemispherical membrane template;
growing nanowires inside the plurality of pores of the hemispherical membrane template to form a nanowire array;
assembling the hemispherical structure and the hemispherical membrane template by aligning the pinhole array with the nanowire array; and
fabricating a plurality of contacts coupled to the nanowire array in the hemispherical membrane template.

15. The method according to claim 14, wherein the hemispherical structure is a honeycombed hemispherical structure, and the hemispherical structure with the pinhole array is 3D-printed.

16. The method according to claim 14, wherein growing the nanowires inside the plurality of pores of the hemispherical membrane template to form the nanowire array comprises:
growing residual nanowires inside the plurality of pores of the hemispherical membrane template; and
growing perovskite nanowires onto the residual nanowires inside the plurality of pores of the hemispherical membrane template.

17. The method according to claim 16, further comprising:
fabricating a common electrode layer onto the perovskite nanowires within the hemispherical membrane template,
wherein the plurality of contacts are coupled to the residual nanowires within the hemispherical membrane template.

18. The method according to claim 17, wherein the common electrode layer comprises Indium Tin Oxide (ITO), and the plurality of contacts are made of Indium.

19. A method for detecting an object, the method comprising:
receiving light via a pinhole array (PHA) of a pinhole compound eye (PHCE) system, wherein respective pinholes of the pinhole array receive light corresponding to varying incident angles;
detecting, through a nanowire array of the PHCE system, a light intensity distribution across a plurality of pixels associated with the PHA; and
constructing an image frame based on the detected light intensity distribution across the plurality of pixels.

20. The method according to claim 19, wherein one or more nanowires of the nanowire array is aligned with a corresponding pinhole of the PHA, and wherein each pinhole of the PHA is associated with one or more pixels of the plurality of pixels.
